(19) United States
(12) Patent Application Publication
(10) Pub. No.: US 2018/0350732 A1
(43) Pub. Date: Dec. 6, 2018

(54) SMALL VIAS IN A POLYMER LAYER DISPOSED ON A SUBSTRATE

(71) Applicant: APPLIED MATERIALS, INC., Santa Clara, CA (US)

(72) Inventors: YU GU, Singapore (SG); GUAN HUEI SEE, Singapore (SG); ARVIND SUNDARRAJAN, Singapore (SG)

(21) Appl. No.: 15/664,954

(22) Filed: Jul. 31, 2017

Related U.S. Application Data
(60) Provisional application No. 62/514,000, filed on Jun. 1, 2017.

(51) Int. Cl. H01L 23/498; H01L 21/48

(52) U.S. Cl. CPC H01L 23/49827; H01L 21/486; H01L 21/481

(57) ABSTRACT

A method of processing a substrate includes depositing a polymer layer atop the substrate to cover an exposed conductive layer on the substrate; curing the polymer layer; forming a patterned masking layer atop the cured polymer layer; etching an exposed portion of the polymer layer through the patterned masking layer to form a via through the polymer layer to a top surface of the conductive layer; and removing the patterned masking layer.

### CROSS-REFERENCE TO RELATED APPLICATIONS

This application claims benefit of U.S. provisional patent application Ser. No. 62/514,000, filed Jun. 1, 2017, which is herein incorporated by reference in its entirety.

### FIELD

Embodiments of the present disclosure generally relate to methods of processing substrates and substrates fabricated according to such methods. Specifically, embodiments of the present disclosure relate to substrates having small vias formed in polymer layers disposed on a substrate and methods of fabricating such small vias.

### BACKGROUND

In the fabrication of modern electronic devices, the increasing device density and decreasing device dimensions demand more stringent requirements in the packaging or interconnecting techniques of such high density devices. Generally, the fabrication of modern electronics involves substrate level packaging. Substrate level packaging generally includes creating vias and similar structures for providing internal and external device connectivity, for example input/output (I/O) connectivity. Creating vias typically involves the use of a polymer material having dielectric properties and stress buffering capabilities. However, the inventors have observed that as via sizes scale down, small polymer via openings cannot be reliably formed and maintained without compromising the dielectric properties of the polymer materials.

Thus, the inventors have developed improved techniques to fabricate polymer vias.

### SUMMARY

Embodiments of methods for creating a small via polymer opening on a substrate are provided herein. In some embodiments, a method of processing a substrate having a conductive layer includes: (a) depositing a polymer layer atop the substrate to cover an exposed conductive layer on the substrate; (b) curing the polymer layer; (c) forming a patterned masking layer atop the cured polymer layer; (d) etching an exposed portion of the polymer layer through the patterned masking layer to form a via through the polymer layer to a top surface of the conductive layer; and (e) removing the patterned masking layer.

In some embodiments, a method of processing a substrate having a conductive layer includes: (a) depositing a polymer layer atop the substrate; (b) curing the polymer layer; (c) depositing a hard mask layer atop the polymer layer; (d) forming a patterned masking layer atop the hard mask layer; (e) etching exposed portions of the hard mask layer through the patterned masking layer to a top surface of the polymer layer; (f) etching exposed portions of the polymer layer through the patterned masking layer and the hard mask layer to a top surface of the conductive layer to form a via through the polymer layer; and (g) removing the patterned masking layer.

In some embodiments, a substrate for a packaging application includes: a cured polymer layer disposed atop a substrate; a conductive layer disposed in the substrate adjacent to and beneath the polymer layer; and a via formed through the cured polymer layer to expose a portion of the conductive layer, wherein the via has a width or diameter of less than 5 microns.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method for forming a via in a polymer layer on a substrate in accordance with at least some embodiments of the present disclosure.

FIGS. 2A-2F schematically depict sequential side views of the stages of forming a via in a polymer layer in accordance with at least some embodiments of the present disclosure.

FIG. 3 depicts a flow chart of a method for forming a via in a polymer layer on a substrate in accordance with at least some embodiments of the present disclosure.

FIGS. 4A-4H schematically depict sequential side views of the stages of forming a via in a polymer layer in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods for forming vias in a polymer layer on a substrate are provided herein. The methods described herein advantageously provide the creation, on a substrate, of a small-sized via (e.g., less than 5 microns in width, or from about 1 to about 5 microns in width) having substantially vertical sidewalls. Small vias as disclosed herein advantageously facilitate direct via-stacked-on-via designs that further improve the allowable I/O density. Thus, the methods described herein may advantageously be utilized in advanced substrate-level packaging and in fan-out substrate level packaging for via critical dimension (CD) scaling.

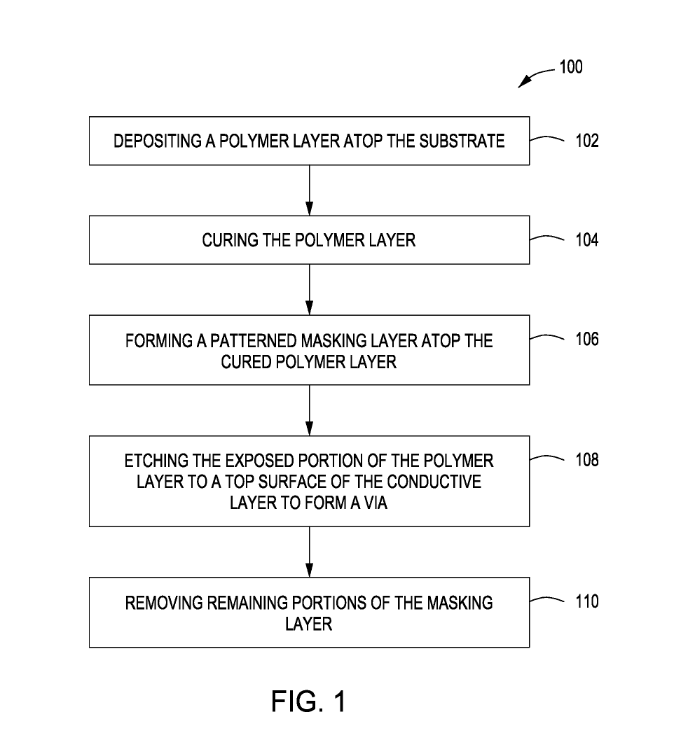

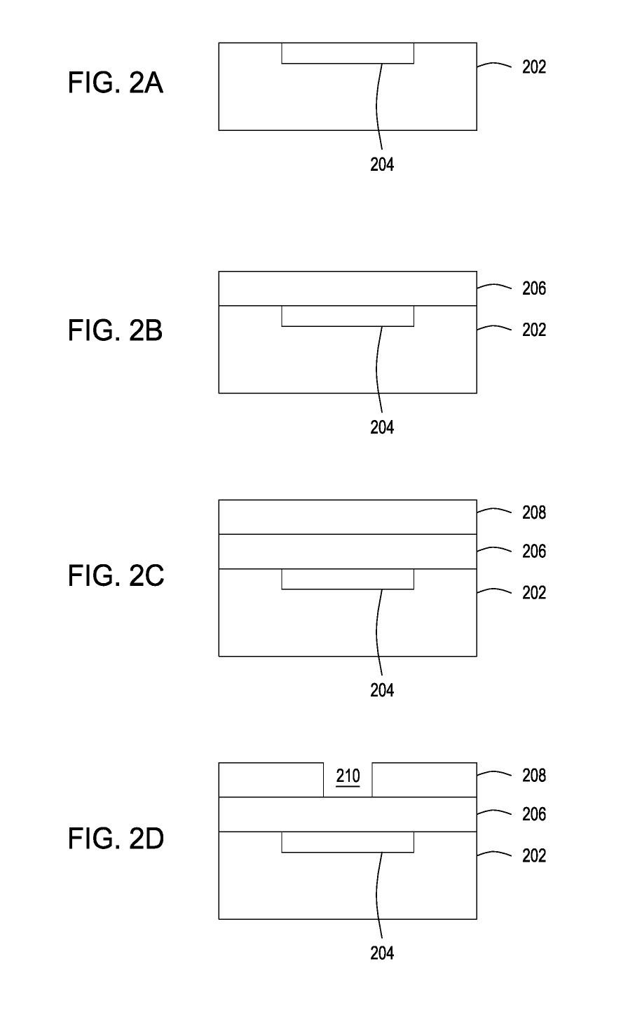

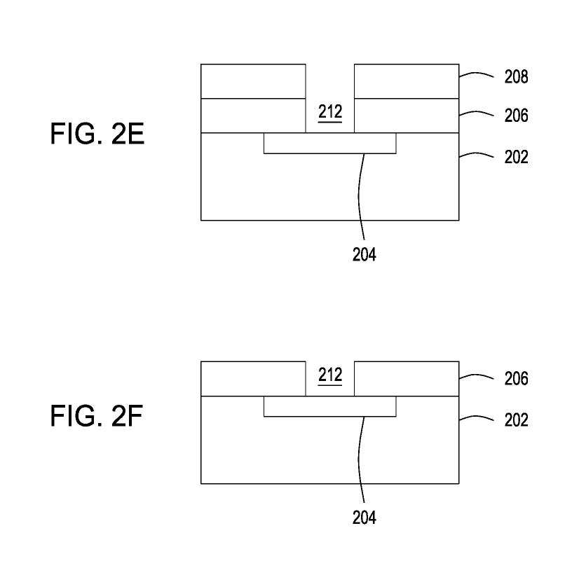

FIG. 1 depicts a flow chart of a method 100 for forming a via in a polymer layer in accordance with at least some embodiments of the present disclosure. The method 100 is described below in accordance with the stages of substrate packaging depicted in FIGS. 2A-2F. Each of FIGS. 2A-2F include a schematic side view for the particular stage of fabrication. The method 100 may be performed in any suitable process chambers configured for the processes described below. Exemplary processing chambers and systems that may be used to perform the inventive methods disclosed herein may include, but are not limited to, various processing systems commercially available from Applied Materials, Inc., of Santa Clara, Calif. Other process chambers, including ones available from other manufacturers, may also be suitably used in connection with the teachings provided herein.

The method 100 is performed on a substrate, such as the substrate 202 depicted in FIG. 2A. In some embodiments, the substrate 202 is composed of a material used in a semiconductor manufacturing process. For example, the substrate 202 may comprise one or more of silicon (Si), germanium, silicon germanium, doped or undoped polysilicon, doped or undoped silicon, and patterned or non-patterned silicon on insulators (SOI), or the like. The substrate 202 may have various dimensions, such as 150 mm, 200 mm, 300 mm or 450 mm diameters or other dimensions. In addition, the substrate 202 may include additional layers of materials or may have one or more completed or partially completed structures or devices formed in or on the substrate 202.

For example, the substrate 202 may include a number of metallization levels having one or more conductive layers, such as metal traces, or the like. One of these conductive layers 204 is shown in FIGS. 2A-2F. As depicted in FIG. 2A, the conductive layer 204 in the substrate 202 is partially exposed through a dielectric top portion of the substrate 202. The conductive layer 204 may comprise any suitable conductive material, such as copper (Cu), aluminum (Al), gold (Au), silver (Ag), or alloys thereof.

For example, the conductive layer 204 may be part of a dielectric layer deposited atop the substrate 202. In some embodiments, the dielectric layer may a low-k dielectric material (e.g., a material having a dielectric constant less than silicon oxide, or less than about 3.9). Examples of suitable dielectric materials include silicon dioxide (SiO₂), fluorine-doped silicon dioxide, carbon-doped silicon dioxide, porous silicon dioxide, porous carbon-doped silicon dioxide, a spin-on organic polymeric dielectric, or a spin-on silicon based polymeric dielectric. When present, the dielectric may be deposited by using any suitable deposition method used for such materials in semiconductor manufacturing processes. The dielectric layer may be deposited to a thickness of, for example, about 100 to about 2,000 angstroms. The thickness of the first dielectric layer varies depending upon factors such as the technology node, the architecture design, the process flow scheme, or the like.

The method generally begins at 102, and as depicted in FIG. 2B, by depositing a polymer layer 206 directly atop the substrate 202 and hence atop the exposed portion of the conductive layer 204. The polymer layer 206 may be photo-patternable (e.g., using photolithography or the like), or not photo-patternable. For example, in some embodiments, such as for negative tone applications, the polymer layer 206 comprises one or more polyimide (PI) compounds. In some embodiments, such as for positive tone applications, the polymer layer 206 comprises polybenzoxazole (PBO). In some embodiments, the polymer layer 206 can include benzocyclobutene, epoxy, or the like.

Generally, in substrate packaging applications consistent with the embodiments of the present disclosure, the polymer layer 206 is provided to act as a dielectric with stress buffering properties. Accordingly, the polymer layer 206 has a combination of mechanical properties configured to ensure robust chip-package reliability (e.g., thermal cycling, drop test, etc.).

In some embodiments, the polymer layer 206 is blanket deposited (i.e. deposited atop the entire exposed surface of the conductive layer 204 to advantageously reduce or eliminate roughness at the interface of the substrate 202 and the conductive layer 204. The polymer layer 206 may be deposited to a thickness of, for example, about 3 microns to about 7 microns, for example, about 6.8 microns. The thickness of the polymer layer 206 can vary depending upon factors such as the technology node, the architecture design, the process flow scheme, or the like. The polymer layer 206 may be deposited using any suitable deposition method commonly used in substrate packaging processes.

Next at 104, the polymer layer 206 is cured. The polymer layer 206 is cured at temperatures that harden and improve the physical and chemical properties of the polymer layer 206. In some embodiments, the curing temperature of the polymer layer 206 may be significantly higher than the temperatures used in performing other processing steps of the method 100. In some embodiments, for example, where the polymer layer 206 comprises PI or PBO, the polymer layer 206 may be cured at a temperature from about 180° C. to about 350° C. In some embodiments, the polymer layer 206 is cured using convective heating. In some embodiments, microwave energy, for example, variable frequency microwave (VFM) energy maybe used to cure the polymer layer 206.

Typically, the resolution limit for negative-tone polymers, for example polymide (PI), is about 8 to about 10 microns. Moreover, the inventors have observed that a negative-tone polymer via (e.g., PI polymer via) opening typically exhibits abnormal shape and may not be properly opened to a resolution below about 8 microns. The typical resolution limit for a positive-tone polymer via, for example polybenzoxazole (PBO) is 5 microns. Thus, vias formed directly in these polymer layers by photo-patterning the polymer layer itself requires larger via sizes. The inventors have observed that forming vias having smaller dimensions would be advantageous in applications such as wafer level and/or fan-out wafer level packaging. In addition, the inventors believe that a reduced polymer via size is advantageous to reduce effective area needed for via formation, thus allowing for more connectivity. The inventors believe that the reduced effective area needed for via formation would be especially valuable for very high I/O connectivity applications, e.g., die partitioning of field programmable gate arrays (FPGA).

As such, next, at 106, a patterned masking layer 208 is formed atop the cured polymer layer 206 to facilitate etching a via into the polymer layer 206 (as depicted in FIGS. 2C-2D). The resolution of the patterned masking layer 208 is lower than the resolution of the polymer layer 206, advantageously facilitating fabrication of smaller-sized features. Forming the patterned masking layer 208 begins with depositing material of the patterned masking layer 208 atop the cured polymer layer 206, as depicted in FIG. 2C.

The patterned masking layer 208 may be formed according to any process suitable to form a masking layer capable of providing an adequate template for defining a pattern in the underlying layer. In some embodiments, the patterned masking layer 208 may be spin coated on the polymer layer 206. In some embodiments, the patterned masking layer 208 may be formed through an etch process, such as a plasma-based dry etching process. The patterned masking layer 208 may be any suitable masking material, such as a photoresist. In some embodiments, the patterned masking layer 208 is provided as a negative photoresist. In some embodiments, the patterned masking layer 208 is provided as a positive photoresist. In some embodiments, the patterned masking layer 208 is an oxygen-containing layer, for example, a silicon oxide (SiOₓ) layer or a silicon oxynitride (SiON) layer.

The thickness of the patterned masking layer 208 is more than, equal to or less than the thickness of the polymer layer 206. For example, in some embodiments, when the polymer layer 206 is deposited to a thickness of about 3 to about 7 microns, for example 6.8 microns, the masking layer may be deposited to a thickness of about 3 microns. The patterned masking layer 208 is deposited on the polymer layer 206 to ensure the formation of a sturdy small via, capable of withstanding other process steps, such as removal of portions of the patterned masking layer 208.

As depicted in FIG. 2D, an opening 210 is formed through a portion of the patterned masking layer 208. The opening 210 includes one or more sidewalls defined by portions of the patterned masking layer 208 and a bottom defined by an exposed top portion of the polymer layer 206. Although only one opening 210 is shown, the patterned masking layer 208 may include a plurality of openings corresponding to a plurality of vias to be formed in the polymer layer 206 (e.g., via 212 discussed below). Each opening 210 has dimensions selected to facilitate the creation of a small via (e.g., an opening with a dimension less than about 5 microns, such from about 1 micron to about 4 microns, or less than or equal to about 2 microns, such as a square area having an area of about 2×2 microns, or a circular area having a diameter of about 2 microns).

Next at 112, and as depicted in FIG. 2E, the opening 210 is further deepened to form a via 212. The via 212 is formed by etching the exposed portion of the polymer layer 206 to a top surface of the conductive layer 204. The etching process may be any etching process suitable for etching materials of the polymer layer 206. In some embodiments, the etching process may be a plasma-based dry etching process. For example, the polymer layer 206 may be exposed to an etching plasma through the opening 210 of the patterned masking layer 208. The etching plasma may be formed from any suitable gases used to etch polymers, such as an oxygen-containing gas, for example oxygen (O₂) gas. The plasma conditions and etch rate are selected based on the thickness of the polymer layer 206 and the desired CD of the etched feature, for example, the CD of the via 212 (e.g., the width or diameter of the via).

Next at 114, as depicted in FIG. 2F, remaining portions of the patterned masking layer 208 are removed. The removal of the patterned masking layer 208 may be done in any suitable manner, such as via a stripping agent (such as EKC photoresist removers available from DuPont) or a plasma process (such as oxygen gas (O₂) plasma strip).

The removal of the patterned masking layer 208 leaves behind the via 212 having a depth equal to the thickness of the polymer layer 206 and a width equal to the desired via width. The sidewalls of the via 212 are vertical or substantially vertical. For example, in some embodiments, the sidewalls of the via 212 may have a vertical angle profile of about 80 to 90 degrees. The bottom of the via 212 is an exposed portion of the conductive layer 204.

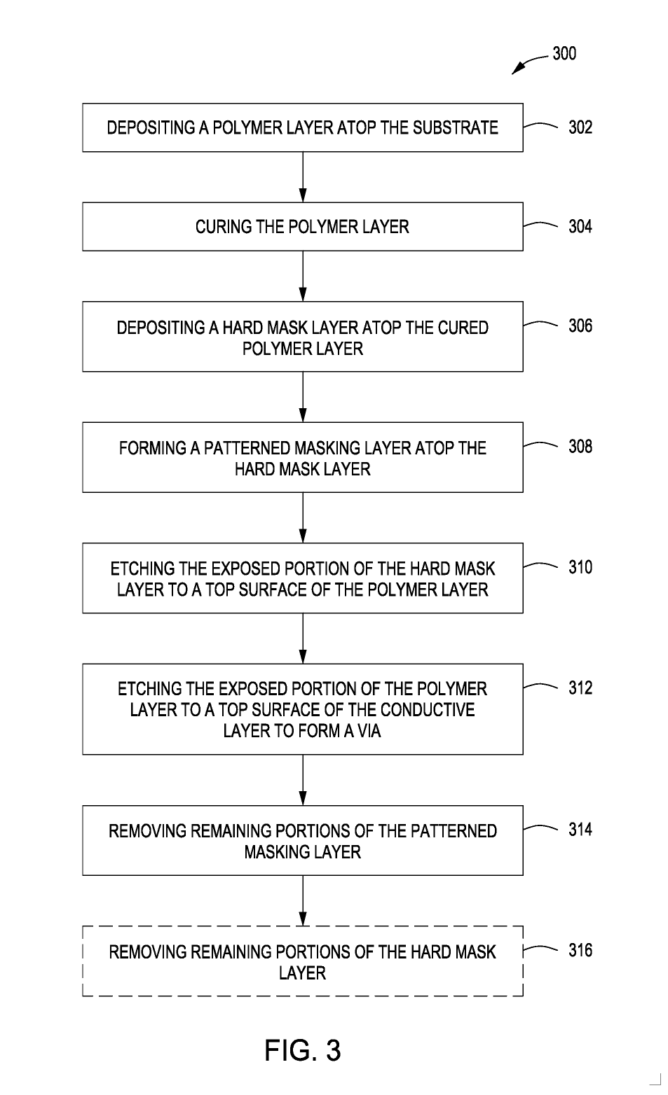

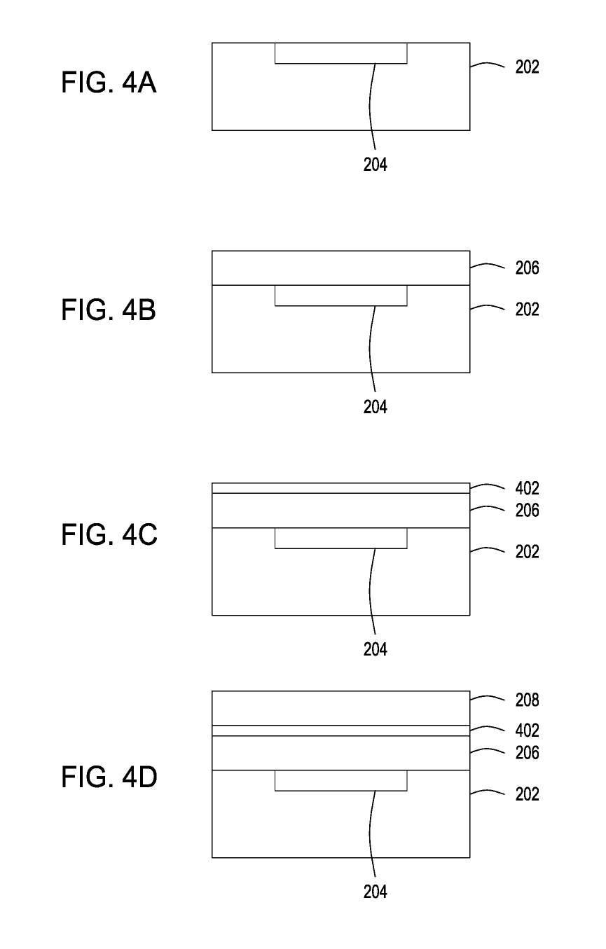

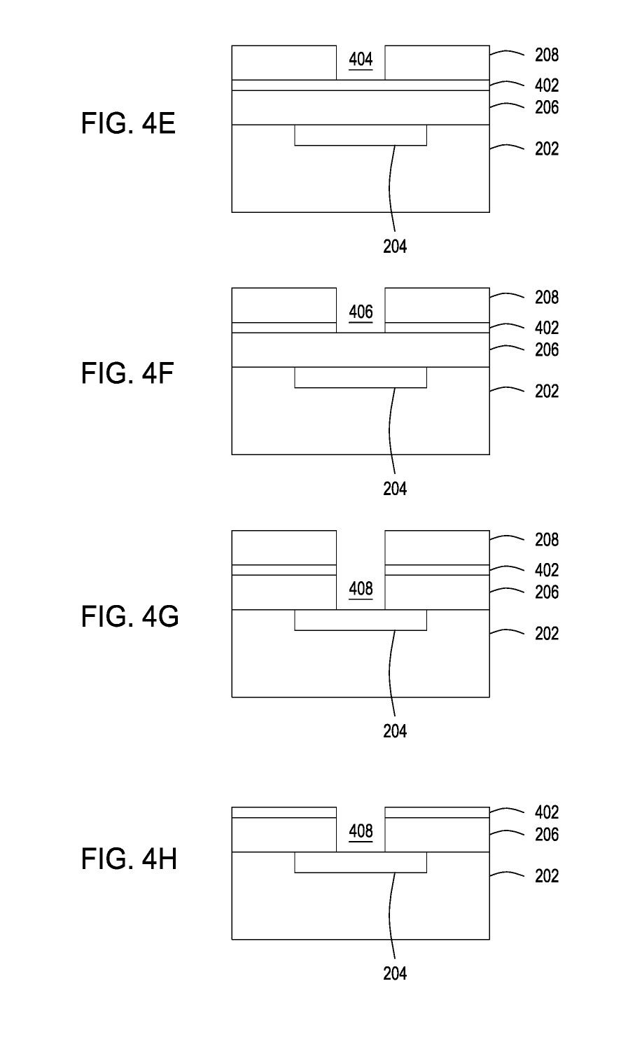

FIG. 3 depicts a flow chart of a method 300 for forming a via in a polymer layer in accordance with at least some embodiments of the present disclosure. The method 100 is described below in accordance with the stages of substrate packaging depicted in FIGS. 4A-4H. Each of FIGS. 4A-4H include a schematic side view for the particular stage of fabrication. The method 300 may be performed in any suitable process chambers configured for the processes described below.

The method 300 begins at 302. At 302, and as depicted in FIG. 4B, the polymer layer 206 is deposited on the substrate 202 and subsequently cured at 304, similar to method 100 and FIG. 2B described above.

Next at 306, and as depicted in FIG. 4C, a hard mask layer 402 is deposited atop the cured polymer layer 206. The hard mask layer 402 provides better control of via profile angle, as plasma dry etching of the polymer layer has low etch selectivity between the patterned masking layer (e.g., photoresist) and the polymer layer, but higher etch selectivity to inorganic or metal materials. In some embodiments, the hard mask layer 402 is formed from an inorganic material. For example, in some embodiments, the hard mask layer 402 may be a silicon and oxygen-containing or a silicon and nitrogen-containing layer comprising, for example, a silicon oxide (SiOₓ), silicon nitride (SiNₓ), or silicon oxynitride (SiON). The inorganic material can be deposited using any suitable method known in the art. In some embodiments, for example, where the polymer layer 206 has a thickness of about 3 microns to about 7 microns, the inorganic material hard mask layer 402 is deposited to a thickness of about 100 to about 1000 angstroms

In some embodiments, the hard mask layer 402 is formed from a metal, for example, titanium, copper, or tantalum. The metal can be deposited using any suitable method known in the art. In some embodiments, for example, where the polymer layer 206 has a thickness of about 3 microns to about 7 microns, the metal hard mask layer 402 is deposited to a thickness of about 100 to about 1000 angstroms.

Next at 308, and as depicted in FIG. 4D, the patterned masking layer 208 is formed atop the polymer layer 206 similar to the manner discussed above in the description of method 100 at 106. As depicted in FIG. 4E, the patterned masking layer 208 includes a first opening 404. The first opening 404 has sidewalls defined by portions of the patterned masking layer 208 and a bottom defined by an exposed top portion of the hard mask layer 402.

Next at 310, and as depicted in FIG. 4F, the first opening 404 is further deepened by etching the exposed portion of the hard mask layer 402 to a top surface of the polymer layer 206, to form a second opening 406. The hard mask layer 402 is etched according to a first etching process. The first etching process is a plasma based dry etching process having a halogen-containing gas etchant. For example, the halogen-containing gas may be a chlorine-containing gas such as carbon tetrachloride (CCl₄), methyl trichloride (CHCl₃), octachlorocyclobutane (C₄Cl₈), hexachlorobutadiene (C₄Cl₆), nitrogen trichloride (NCl₃), sulfur hexachloride (SCl₆), or the like. The plasma conditions and etch rate are selected based on the material and thickness of the hard mask layer 402 and the desired CD of the etched feature (e.g., the CD of the via 408).

Next at 312, and as depicted in FIG. 4G, the second opening 406 is further deepened by etching the exposed portion of the polymer layer 206 to a top surface of the conductive layer 204, to form a via 408. The polymer layer 206 is etched according to a second etching process. The second etching process is the same as discussed above with respect to etching the polymer layer 206 in the method 100.

Next at 314, as depicted in FIG. 4H, remaining portions of the patterned masking layer 208 are removed. The patterned masking layer 208 is removed in the same manner as discussed above with respect the method 100.

In embodiments, where the hard mask layer 402 is an inorganic material, the method 300 may end at 314 with the removal of the patterned masking layer 208. However, in embodiments where the hard mask layer is a metal, the method 300 includes a further process 316 to remove remaining portions of the hard mask layer 402. When provided as a metal, the hard mask layer 402 is removed to prevent the creation of an unwanted conductive path between the hard mask layer 402 and the conductive layer 204. In some embodiments, the metal is removed using a suitable wet etch process, for example, using H₂O₂, or the like.

The removal of the patterned masking layer 208, or alternatively of both the patterned masking layer 208 and the hard mask layer 402 leaves behind the via 408 having a depth equal to the thickness of the polymer layer 206 (e.g., about 6.8 microns) and a width equal to the desired via width (e.g., about 2 microns). The sidewalls of the via 408 are vertical or substantially vertical. For example, in some embodiments, the sidewalls of the via 212 may have a vertical angle profile of about 80 degrees and about 90 degrees, for example, about 89 degrees. The bottom of the via 212 is an exposed portion of the conductive layer 204.

Thus, methods of forming vias in polymer layers have been provided herein. The vias can advantageously have a smaller size than typically possible when photo-patterning the vias directly in the polymer layer. The opening created in the polymer layer with a dry plasma etch has better resolution (e.g., <=2 μm) with better control of via CD uniformity and profile angle, as the opening geometry is no longer dependent on polymer dielectric lithography properties. Methods in accordance with the present disclosure thus further advantageously open up the possibility to switch to cheaper and better, non-photo sensitive polymers to function as the polymer layer. Improved via resolution further provides improved I/O density and also allows for direct via-stacked-on-via designs that further improve the allowable I/O density.

While the foregoing is directed to embodiments of the present disclosure, other and further embodiments of the disclosure may be devised without departing from the basic scope thereof.

1. A method of processing a substrate having a conductive layer, comprising:
(a) depositing a polymer layer atop a substrate to cover an exposed conductive layer on the substrate;
(b) curing the polymer layer;
(c) forming a patterned masking layer directly atop the cured polymer layer;
(d) etching an exposed portion of the cured polymer layer through the patterned masking layer to form a via through the cured polymer layer to a top surface of the conductive layer; and
(e) removing the patterned masking layer.

2. The method of claim 1, wherein the polymer layer is thicker than the patterned masking layer.

3. The method of claim 1, wherein the polymer layer has a thickness of about 3 microns to about 7 microns.

4. The method of claim 1, wherein the patterned masking layer has a thickness of about 3 to about 10 microns.

5. The method of claim 1, wherein the patterned masking layer has a resolution that is less than the resolution of the polymer layer.

6. The method of claim 1, wherein the polymer layer includes one or more polyimide (PI) compounds.

7. The method of claim 1, wherein the patterned masking layer is a photoresist.

8. The method of claim 1, wherein the exposed portion of the polymer layer is etched with a plasma-based dry etching process.

9. The method of claim 1, wherein the via has a width of about 1 micron to about 5 microns.

10. The method of claim 1, wherein the via has a sidewall profile angle of about 80 degrees and about 90 degrees.

11. A method of processing a substrate having a conductive layer, comprising:
(a) depositing a polymer layer atop a substrate;
(b) curing the polymer layer;
(c) depositing a hard mask layer atop the cured polymer layer;
(d) forming a patterned masking layer atop the hard mask layer;
(e) etching exposed portions of the hard mask layer through the patterned masking layer to a top surface of the cured polymer layer;
(f) etching exposed portions of the cured polymer layer through the patterned masking layer and the hard mask layer to a top surface of the conductive layer to form a via through the cured polymer layer; and
(g) removing the patterned masking layer.

12. The method of claim 11, wherein the hard mask layer is an inorganic material.

13-20. (canceled)

21. A method of processing a substrate having a conductive layer, comprising:
(a) depositing a polymer layer atop a substrate to cover an exposed conductive layer on the substrate, wherein the polymer layer has a thickness of about 3 microns to about 7 microns;
(b) curing the polymer layer to form a cured polymer layer having a top surface;
(c) forming a patterned masking layer atop and in contact with the top surface of the cured polymer layer;
(d) etching an exposed portion of the cured polymer layer through the patterned masking layer to form a via through the cured polymer layer to a top surface of the conductive layer; and
(e) removing the patterned masking layer.

22. The method of claim 21, wherein the polymer layer includes one or more polyimide compounds.

23. The method of claim 21, wherein the via has a width of about 1 micron to about 5 microns.

24. The method of claim 21, wherein the via has a sidewall profile angle of about 80 degrees and about 90 degrees.

25. The method of claim 21, wherein the patterned masking layer is a photoresist.

26. The method of claim 21, wherein the exposed portion of the cured polymer layer is etched with a plasma-based dry etching process.
